(19) United States
(12) Patent Application Publication
(10) Pub. No.: US 2026/0068364 A1
(43) Pub. Date: Mar. 5, 2026

(54) LIGHT-EMITTING DIODE AND MANUFACTURING METHOD THEREOF AND LIGHT-EMITTING DEVICE

(71) Applicant: Xiamen San'an Optoelectronics Co., Ltd., Fujian (CN)

(72) Inventors: Heying TANG, Fujian (CN); Jenlung YANG, Fujian (CN); Liming ZHANG, Fujian (CN); Xingrong CHEN, Fujian (CN)

(73) Assignee: Xiamen San'an Optoelectronics Co., Ltd., Fujian (CN)

(21) Appl. No.: 19/313,880

(22) Filed: Aug. 29, 2025

(30) Foreign Application Priority Data
Aug. 29, 2024 (CN) 202411199688.0
Aug. 29, 2024 (CN) 202411203528.9

(51) Int. Cl. H10H 20/821; H10H 20/01; H10H 20/813; H10H 20/816; H10H 20/831

(52) U.S. Cl. CPC H10H 20/821; H10H 20/017; H10H 20/032; H10H 20/8132; H10H 20/8162; H10H 20/8314

(57) ABSTRACT

Disclosed are a light-emitting diode, a method for manufacturing the same, and a light-emitting device. The light-emitting diode includes a semiconductor stack including a first semiconductor layer, a light-emitting layer and a second semiconductor layer stacked in sequence; when looking down at the semiconductor stack from the top of the light-emitting diode, the semiconductor stack includes a first region and a second region, the first region includes an exposed first semiconductor layer and a retained island; a first current blocking layer located on the island; a second current blocking layer located in the second region; a transparent conductive layer located in the second region and covering the second current blocking layer; a first electrode located on the first current blocking layer and electrically connected to the exposed first semiconductor layer; a second electrode located on the transparent conductive layer and electrically connected to the second semiconductor layer.

### CROSS-REFERENCE TO RELATED APPLICATION

This application claims the priority benefit of China application serial no. 202411199688.0, filed on Aug. 29, 2024, and China application serial no. 202411203528.9, filed on Aug. 29, 2024. The entirety of each of the above-mentioned patent applications is hereby incorporated by reference herein and made a part of this specification.

### BACKGROUND

### Technical Field

The present disclosure relates to semiconductor manufacturing technology, and particularly relates to a light-emitting diode and a light-emitting device.

### Description of Related Art

A light-emitting diode (LED) is typically composed of semiconductors such as GaN, GaAs, GaP, or GaAsP. Its core is a PN junction with light-emitting characteristics. Under forward voltage, electrons are injected from an N region into a P region, and holes are injected from the P region into the N region. A portion of minority carriers entering the opposite region recombines with majority carriers, resulting in light emission. LEDs are characterized by high luminous intensity, high efficiency, compact size, and long service life, and are considered one of the most promising light sources currently available.

### SUMMARY

An embodiment of the present disclosure provides a light-emitting diode. The light-emitting diode includes:

A substrate, having an upper surface and a lower surface arranged opposite to each other;

A semiconductor stack, arranged on the upper surface of the substrate, including a first semiconductor layer, a light-emitting layer, and a second semiconductor layer stacked in sequence;

When looking down at the semiconductor stack from the top of the light-emitting diode, the semiconductor stack includes a first region and a second region, the first region includes an exposed first semiconductor layer and a retained island;

A first current blocking layer, located on the island;

A second current blocking layer, located in the second region;

A transparent conductive layer, located in the second region and covering the second current blocking layer;

A first electrode, located on the first current blocking layer and electrically connected to the exposed first semiconductor layer; and

A second electrode, located on the transparent conductive layer and electrically connected to the second semiconductor layer.

According to another embodiment of the present disclosure, a manufacturing method of a light-emitting diode element is provided. The manufacturing method includes the following steps:

(1) Providing a substrate, growing a semiconductor stack on an upper surface of the substrate, the semiconductor stack being formed by sequentially stacking a first semiconductor layer, a light-emitting layer, and a second semiconductor layer;

(2) Forming a first current blocking layer below a first electrode to be plated and a second current blocking layer below a second electrode to be plated;

(3) Forming the entire transparent conductive layer;

(4) Defining a first region and a second region on the semiconductor stack, etching away a portion of the transparent conductive layer in the first region and the semiconductor stack below until the first semiconductor layer is exposed, while retaining the remaining transparent conductive layer in the first region that is not etched and the semiconductor stack below to form an island;

(5) Removing the transparent conductive layer on the island, and forming an opening on the transparent conductive layer in the second region;

(6) Forming a first electrode on the island and forming a second electrode on the transparent conductive layer respectively, the second electrode forming an electrical connection with the second semiconductor layer through the opening on the transparent conductive layer.

According to another embodiment of the present disclosure, a light-emitting diode is also provided. The light-emitting diode includes:

A substrate, having an upper surface and a lower surface arranged opposite to each other;

A semiconductor stack, arranged on the upper surface of the substrate, including a first semiconductor layer, a light-emitting layer, and a second semiconductor layer stacked in sequence;

When looking down at the semiconductor stack from the top of the light-emitting diode, the semiconductor stack includes a first region and a second region, the first region includes an exposed first semiconductor layer and a retained island; the island has an upper surface and a lower surface arranged opposite to each other, and a near edge and a far edge, a distance from the near edge to the second region is less than a distance from the far edge to the second region;

A first electrode, located on the island, at least partially covering the upper surface and the far edge of the island, and electrically connected to the exposed first semiconductor layer;

A second electrode, located in the second region and electrically connected to the second semiconductor layer.

According to another embodiment of the present disclosure, a light-emitting diode is also provided, which at least includes:

A substrate, having an upper surface and a lower surface arranged opposite to each other;

A semiconductor stack, arranged on the upper surface of the substrate, including a first semiconductor layer, a light-emitting layer, and a second semiconductor layer stacked in sequence; the semiconductor stack is provided with a step sequentially passing through a portion of the second semiconductor layer and the light-emitting layer while extending to the first semiconductor layer, and a step surface exposing a portion of the first semiconductor layer;

A first current blocking layer, located on the step surface, when looking down at the semiconductor stack from the top of the light-emitting diode, the first current blocking layer has a near edge and a far edge, a distance from the near edge to the step is less than a distance from the far edge to the step;

A first electrode, located on the first current blocking layer, at least partially covering the upper surface and the far edge of the first current blocking layer, and electrically connected to the exposed first semiconductor layer;

A second electrode, located on the second semiconductor layer and electrically connected to the second semiconductor layer.

According to another embodiment of the present disclosure, a light-emitting device is also provided, adopting the light-emitting diode described in any one of the above embodiments.

In order to achieve a large area of the transparent conductive layer, existing light-emitting diodes typically employ a method of patterning both the transparent conductive layer and the semiconductor stack based on the same photomask. This approach effectively reduces a distance from an edge of the transparent conductive layer to an edge of the second semiconductor layer, thereby increasing the light-emitting area. However, this process often fails to retain the current blocking layer beneath an N-type electrode, or an additional manufacturing step is required to form the current blocking layers beneath the P-type and N-type electrodes separately, which leads to increased costs.

The present disclosure provides a light-emitting diode (LED) by retaining an island on the semiconductor stack and positioning an N-type current blocking layer beneath the N-type electrode on the retained island. This configuration enables the expansion of the light-emitting area without increasing costs, while simultaneously preserving the current blocking layer beneath the N-type electrode. Consequently, this effectively mitigates current crowding beneath the N-type electrode, promotes lateral current spreading, and facilitates the formation of an effective omni-directional reflector (ODR) reflective layer, thereby enhancing reflection efficiency and further improving an optoelectronic performance of the LED.

The present disclosure further enhances the reliability of the light-emitting diode by optimizing the design of the position of the first electrode, thereby increasing the distance between the first electrode and the second electrode. This design reduces the electric field intensity and enhances the resistance to metal migration.

### BRIEF DESCRIPTION OF THE DRAWINGS

FIG. 1 is a schematic cross-sectional view of a light-emitting diode provided in an embodiment of the present disclosure.

FIG. 2 is a schematic view of a partial enlarged view of a region A in FIG. 1.

FIG. 3 is a schematic top view of the light-emitting diode provided in the first embodiment of the present disclosure.

FIG. 4 is a schematic view of a first region and a second region provided by an embodiment of the present disclosure.

FIG. 5 is a schematic cross-sectional view of a structure of a light-emitting diode provided in the second embodiment of the present disclosure.

FIG. 6 is a schematic top view of the light-emitting diode provided in the second embodiment of the present disclosure.

FIG. 7 is a schematic cross-sectional view of a structure of a light-emitting diode provided in the third embodiment of the present disclosure.

FIG. 8 is a schematic top view of the light-emitting diode provided in the third embodiment of the present disclosure.

FIG. 9 is a schematic cross-sectional view of a structure of a light-emitting diode provided in the fourth embodiment of the present disclosure.

FIG. 10 is a schematic flow chart of a manufacturing method of a light-emitting diode provide in the fifth embodiment of the present disclosure.

FIG. 11 to FIG. 16 are schematic views of the steps of the manufacturing method of the light-emitting diode provide in the fifth embodiment of the present disclosure.

FIG. 17 is a schematic cross-sectional side view of a structure of a light-emitting diode provided in the sixth embodiment of the present disclosure.

FIG. 18 is a partial enlarged view of a region A in FIG. 17.

FIG. 19 is a schematic top view of a light-emitting diode provided in the sixth embodiment of the present disclosure.

FIG. 20 is a schematic cross-sectional view of a structure of another light-emitting diode provided in an embodiment of the present disclosure.

FIG. 21 is a schematic cross-sectional view of a structure of yet another light-emitting diode provided by an embodiment of the present disclosure.

FIG. 22 is a schematic top view of still another light-emitting diode provided in the seventh embodiment of the present disclosure.

FIG. 23 is a schematic cross-sectional view of a structure of a light-emitting diode provided in the eighth embodiment of the present disclosure.

FIG. 24 is a schematic top view of the light-emitting diode provided in the eighth embodiment of the present disclosure.

FIG. 25 is a schematic top view of yet another light-emitting diode provided by an embodiment of the present disclosure.

FIG. 26 is a schematic cross-sectional view of a structure of a light-emitting diode provided in the ninth embodiment of the present disclosure.

FIG. 27 is a schematic top view of the light-emitting diode provided in the ninth embodiment of the present disclosure.

### DESCRIPTION OF THE EMBODIMENTS

To make the objectives, technical solutions, and advantages of the embodiments of the present disclosure clearer, the technical solutions in the embodiments of the present disclosure will be described clearly and completely below in conjunction with the drawings in the embodiments of the present disclosure. The technical features designed in different embodiments of the present disclosure described below may be combined with each other as long as they do not conflict with each other.

### First Embodiment

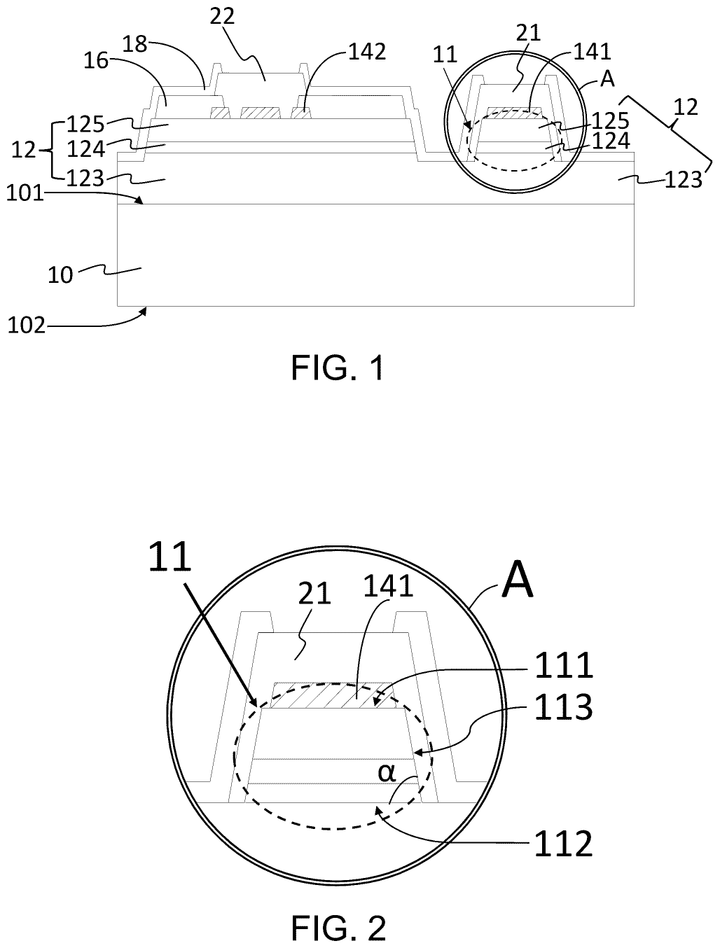

Refer to FIG. 1 and FIG. 2, FIG. 1 is a schematic cross-sectional view of a light-emitting diode provided in an embodiment of the present disclosure. FIG. 2 is a schematic view of a partial enlarged view of a region A in FIG. 1. To achieve at least one of the aforementioned advantages or other advantages, an embodiment of the present disclosure provides a light-emitting diode. The light-emitting diode may at least include a substrate 10, a semiconductor stack 12, a first electrode 21, a second electrode 22, a first current blocking layer 141, a second current blocking layer 142, and a transparent conductive layer 16.

The substrate 10 has an upper surface 101 and a lower surface 102 disposed opposite to each other. The substrate 10 may be a transparent substrate or a non-transparent substrate or a semi-transparent substrate, wherein the transparent substrate or the semi-transparent substrate may allow light radiated from a light-emitting layer to pass through the substrate 10 to reach one side of the substrate 10 away from the semiconductor stack 12. For example, the substrate 10 may be any one of a sapphire flat substrate, a sapphire patterned substrate, a silicon substrate, a silicon carbide substrate, a gallium nitride substrate, or a glass substrate. In some embodiments, the substrate 10 may adopt a combined patterned substrate. In other embodiments, the substrate 10 may be thinned or removed to form a thin-film type chip.

The semiconductor stack 12 is disposed on the upper surface 101 of the substrate 10. The semiconductor stack 12 includes a first semiconductor layer 123, a light-emitting layer 124, and a second semiconductor layer 125 stacked in sequence. The first semiconductor layer 123 is formed on the substrate 10, serving as a layer grown on the substrate 10, and may be a gallium nitride-based semiconductor layer doped with n-type impurities, for example, Si. In some embodiments, a buffer layer may also be disposed between the first semiconductor layer 123 and the substrate 10. In other embodiments, the first semiconductor layer 123 may also be connected to the substrate 10 through a bonding layer.

The light-emitting layer 124 may be a quantum well (abbreviated as QW) structure. In some embodiments, the light-emitting layer 124 may also be a multiple quantum well (abbreviated as MQW) structure. The multiple quantum well structure includes multiple quantum well layers and multiple quantum barrier layers alternately arranged in a repeated manner. In addition, the composition and thickness of the well layers in the light-emitting layer 124 determine a wavelength of a generated light. In particular, by adjusting the composition of the well layers, light-emitting layers that generate different colored lights such as ultraviolet light, blue light, green light, yellow light, etc. may be provided.

The second semiconductor layer 125 may be a gallium nitride-based semiconductor layer doped with p-type impurities, for example, Mg. Although the first semiconductor layer 123 and the second semiconductor layer 125 may be single-layer structures respectively, the present disclosure is not limited thereto, and may also be multiple layers, and may also include superlattice layers. In addition, in other embodiments, in the case where the first semiconductor layer 123 is doped with p-type impurities, the second semiconductor layer 125 may be doped with n-type impurities, that is, the first semiconductor layer 123 is a P-type semiconductor layer, and the second semiconductor layer 125 is an N-type semiconductor layer.

Of course, the semiconductor stack 12 may also include other layer materials, such as window layers or ohmic contact layers, etc., which are arranged as different multiple layers according to different doping concentrations or contents of ingredients.

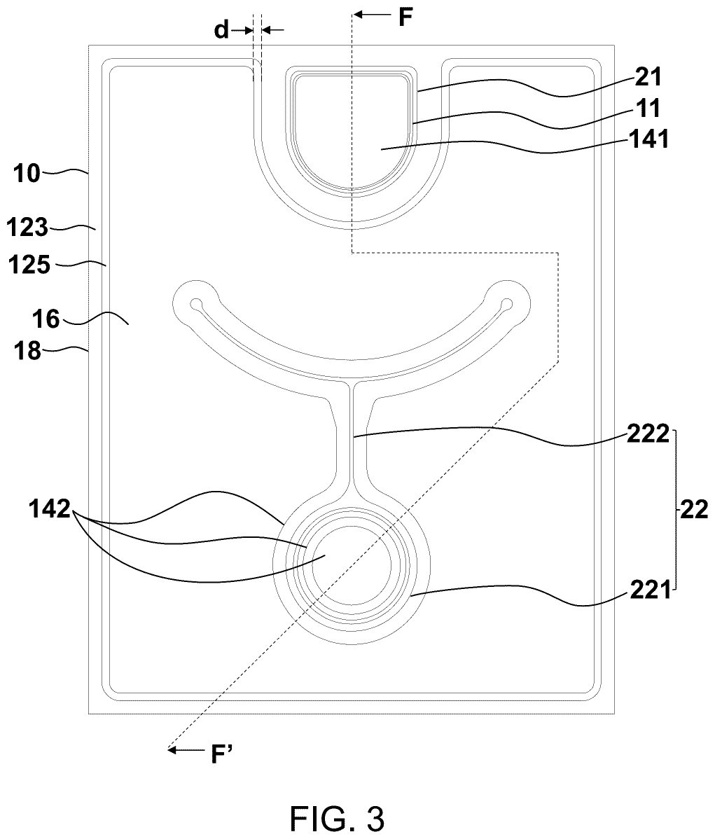

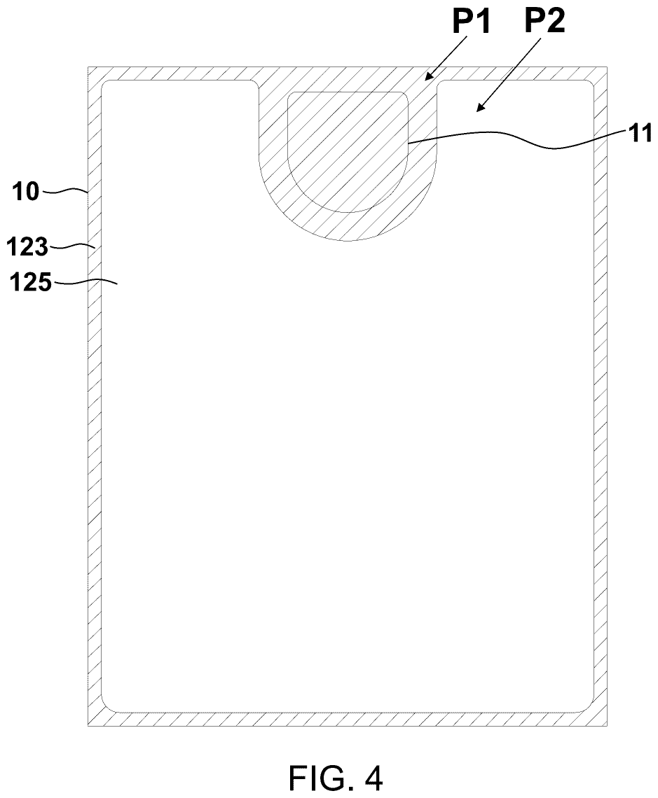

Refer to FIG. 3 and FIG. 4, FIG. 3 is a schematic top view of the light-emitting diode provided in the first embodiment of the present disclosure. FIG. 4 is a schematic view of a first region and a second region provided by an embodiment of the present disclosure. FIG. 1 is a cross-sectional side view taken along a sectional line F-F′ of FIG. 3. When looking down at the semiconductor stack 12 from the top of the light-emitting diode, the semiconductor stack 12 includes the first region P1 and the second region P2. As shown in FIG. 4, to clearly show the shapes of the first region P1 and the second region P2, the first region P1 is shown with a fill pattern. The semiconductor stack 12 etches away portions of the second semiconductor layer 125 and the light-emitting layer 124 to expose the first semiconductor layer 123. The first region P1 includes the exposed first semiconductor layer 123 and a retained island 11. As shown in the figure, the island 11 is at least partially surrounded by the exposed first semiconductor layer 123. The second region P2 includes the first semiconductor layer 123, the light-emitting layer 124, and the second semiconductor layer 125 that are not etched away and stacked in sequence, and the second region P2 refers to all regions in the semiconductor stack 12 except the first region P1.

Continue to refer to FIG. 1 and FIG. 2, the first current blocking layer 141 is located on the island 11. The material of the first current blocking layer 141 is an insulating material, which may be an oxide, and may be a relatively transparent material, such as one or multiple combinations of materials selected from silicon oxide, titanium oxide, silicon nitride, aluminum oxide, magnesium fluoride, spin-on glass (SOG), polymer, etc., and the present disclosure is not limited to the examples listed here. Preferably, the thickness of the first current blocking layer 141 is between 50 nm to 500 nm.

The first electrode 21 is located on the first current blocking layer 141. In the present embodiment, the first electrode 21 completely wraps the first current blocking layer 141 and the island 11, and is electrically connected to the exposed first semiconductor layer 123 through covering sidewalls of the first current blocking layer 141 and the island 11. The first electrode 21 may be a metal electrode, that is, the first electrode 21 is made of a metal material, for example, at least one of nickel, gold, chromium, titanium, platinum, palladium, rhodium, iridium, aluminum, tin, indium, tantalum, copper, cobalt, iron, ruthenium, zirconium, tungsten and molybdenum, or at least one alloy or stack selected from the above materials. As an example, in the present embodiment, the first electrode 21 may be an N electrode. By designing the first electrode 21 to completely wrap the first current blocking layer 141 and the island 11, on one hand, a contact area between the first electrode 21 and the island 11 is increased, which helps to enhance the stability of the first electrode 21, and on the other hand, a contact area between the first electrode 21 and the first semiconductor layer 123 is increased, which helps to increase current channels and reduce voltage.

In order to achieve a large area of the transparent conductive layer, existing light-emitting diodes typically employ a method of patterning both the transparent conductive layer and the semiconductor stack based on the same photomask. This approach effectively reduces a distance from an edge of the transparent conductive layer to an edge of the second semiconductor layer, thereby increasing the area of the transparent conductive layer, which in turn increases the light-emitting area. However, through this process, when patterning the transparent conductive layer and the semiconductor stack, the current blocking layer on the first semiconductor layer will be etched away at the same time, therefore it is often impossible to retain the current blocking layer below the N-type electrode; or if it is required to have the current blocking layer below the N-type electrode, an additional manufacturing process is required to form the current blocking layers on the first semiconductor layer and the second semiconductor layer separately, that is, after patterning the semiconductor stack, an additional manufacturing process is required to form the current blocking layer on the second semiconductor layer, which will lead to increased cost.

The present disclosure defines the semiconductor stack 12 as the first region P1 and the second region P2, and retains the island 11 in the first region P1, while disposing the first current blocking layer 141 on the retained island 11, thereby avoiding etching away the current blocking layer 141 on the first semiconductor layer 123 simultaneously when patterning the transparent conductive layer 16 and the semiconductor stack 12. In this way, it is possible to increase the light-emitting area without increasing the cost. Furthermore, by forming the first electrode 21 on the first current blocking layer 141 on the retained island 11, not only that it is possible to effectively overcome the current crowding phenomenon below the first electrode 21 and promote lateral current spreading, but also a good ODR reflective layer may be formed to enhance reflection efficiency, thus further improving an optoelectronic performance of the light-emitting diode.

The second current blocking layer 142 is located in the second region P2. The first current blocking layer 141 and the second current blocking layer 142 may be formed simultaneously through the same manufacturing process and use the same material, thereby reducing cost.

The transparent conductive layer 16 is located in the second region P2 and covers the second current blocking layer 142. The second current blocking layer 142 is sandwiched between the semiconductor stack 12 and the transparent conductive layer 16. The transparent conductive layer 16 may include at least one of indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), and gallium-doped zinc oxide (GZO). In this embodiment, the transparent conductive layer 16 is preferably an ITO (indium tin oxide semiconductor transparent conductive film) layer formed by an evaporation process or a sputtering process.

The second electrode 22 is located on the transparent conductive layer 16, and is electrically connected to the second semiconductor layer 125 through the transparent conductive layer 16. The second electrode 22 includes a main body portion 221 and at least one extension portion 222. The second electrode 22 corresponds to and contacts the second current blocking layer 142 in a vertical direction, that is, a projection of the second electrode 22 on the second current blocking layer 142 is located inside the second current blocking layer 142. The second current blocking layer 142 serves to block current, avoiding current crowding directly below the second electrode 22 and spreading out. The transparent conductive layer 16 serves as a channel for current flow. Through such design, the current flows through the transparent conductive layer 16 across the entire surface of the second semiconductor layer 125, avoiding current crowding and ensuring that current spreads as much as possible on the surface of the second semiconductor layer 125 to improve light-emitting efficiency. The second electrode 22 may be a metal electrode, that is, the second electrode 22 is made of a metal material, for example, at least one of nickel, gold, chromium, titanium, platinum, palladium, rhodium, iridium, aluminum, tin, indium, tantalum, copper, cobalt, iron, ruthenium, zirconium, tungsten and molybdenum, or at least one alloy or stack selected from the above materials. As an example, the second electrode 22 may be a P electrode. It should be noted that the second current blocking layer 142 in the embodiments of the present disclosure may simultaneously include a first portion and a second portion as shown in the drawings of the present disclosure. The first portion is formed directly below the extension portion 222 and a portion of the main body portion 221 of the second electrode 21. The first portion has an opening directly below the main body portion 221. The second portion is formed within the opening and there is a gap between the second portion and the first portion. In some embodiments, the second current blocking layer 142 may also include only the first portion; in other embodiments, the second current blocking layer 142 may also include only the second portion, the present disclosure is not limited to the examples listed herein.

Please continue to refer to FIG. 3, the edge of the transparent conductive layer 16 is located on the inner side of the edge of the second semiconductor layer 125. There is a spacing d between the edge of the transparent conductive layer 16 and the edge of the second semiconductor layer 125, and the spacing d is not greater than 2.5 μm. Preferably, in some embodiments, the spacing d is not greater than 1.5 μm, for example, 1 μm. By reducing the distance from the edge of the transparent conductive layer 16 to the edge of the second semiconductor layer 125, it is possible to increase the area of the transparent conductive layer 16, and further increase the area of the light-emitting region, thereby further enhancing the brightness of the light-emitting diode. More preferably, in some embodiments, the spacing d is not less than 0.5 μm, for example, the spacing d is between 0.5 μm to 2.5 μm. In this way, it is possible to avoid reverse aging phenomenon caused by residual transparent conductive layer at the edge of the transparent conductive layer 16 due to incomplete etching.

Please continue to refer to FIG. 1, the island 11 includes the first semiconductor layer 123, the light-emitting layer 124, and the second semiconductor layer 125 stacked in sequence. More preferably, in the present embodiment, the upper surface of the island 11 is aligned with the upper surface of the second region P2. By etching a portion of the semiconductor stack 12 to expose the first semiconductor layer 123, it is possible to simultaneously form the island 11 and the second region P2, on one hand, the process is simple and does not require adding additional process steps; on the other hand, the design helps to reduce the height difference between the first electrode 21 and the second electrode 22, facilitating subsequent packaging and wire bonding.

Please continue to refer to FIG. 2, preferably, in an embodiment, the island 11 has an upper surface 111 and a lower surface 112, and a side surface 113 connecting the upper surface 111 and the lower surface 112. An interior angle α formed between the side surface 113 and the lower surface 112 of the island 11 is less than 90°. Preferably, in some embodiments, α is less than 60°. More preferably, in some embodiments, α is less than 45°, for example 30° to 40°, 20° to 30°, etc. By designing the island 11 to have a structure that is narrow at the top and wide at the bottom with the inclined side surface, the inclined side surface helps to enhance the coverage of the first electrode 21. Moreover, it is possible to avoid forming an excessively sharp angle (e.g., close to 90°) between the side surface 113 of the island 11 and the lower surface 112 of the island 11. Such sharp angle could cause the metal stack of the first electrode 21 to break at the corners due to thinner coverage. Correspondingly, designing the interior angle formed between the side surface 113 and the upper surface 111 of the island 11 to be greater than 90° also helps to enhance the coverage of the first electrode 21.

Furthermore, the light-emitting diode may further include an insulating layer 18. The insulating layer 18 covers the semiconductor stack 12, and may also cover a portion of the first electrode 21 and a portion of the second electrode 22. The insulating layer 18 has different functions according to the designed position. For example, when the insulating layer 18 covers the sidewall of the semiconductor stack 12, the design may prevent electrical connection between the first semiconductor layer 123 and the second semiconductor layer 125 due to conductive material leakage, thus reducing the possibility of short circuit abnormalities in the light-emitting diode, but the embodiments of the present disclosure are not limited thereto. The material of the insulating layer 18 includes non-conductive materials. The non-conductive material is preferably an inorganic material or a dielectric material. The inorganic material may include silicone. The dielectric material includes electrically insulating materials such as aluminum oxide, silicon nitride, silicon oxide, titanium oxide, or magnesium fluoride. For example, the insulating layer 18 may be silicon dioxide, silicon nitride, titanium oxide, tantalum oxide, niobium oxide, barium titanate, or combinations thereof, the combinations may be, for example, a Bragg reflector (DBR) formed by repeatedly stacking two materials with different refractive indices.

### Second Embodiment

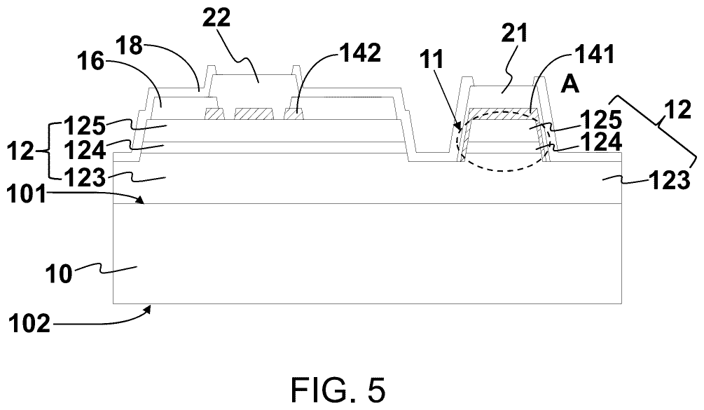

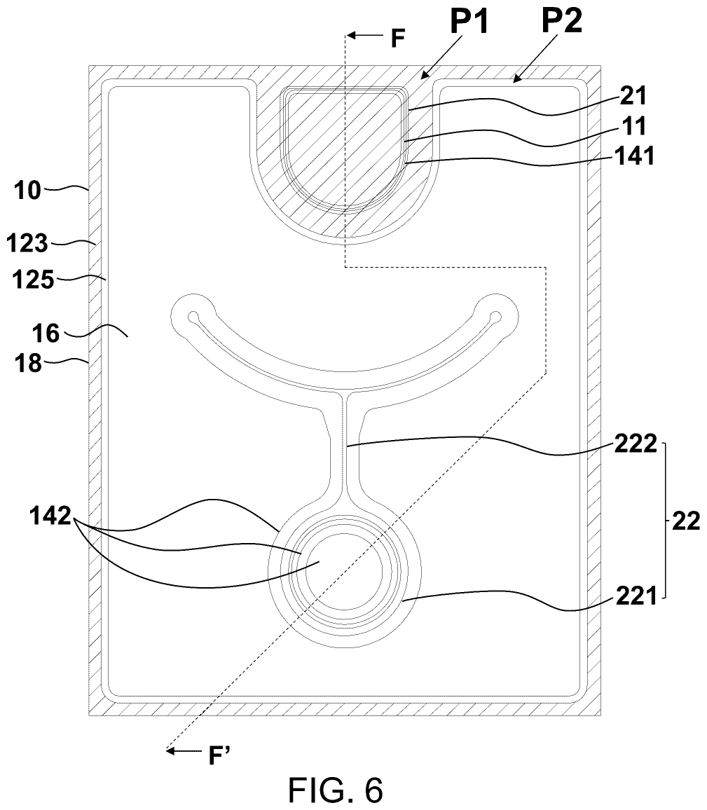

Please refer to FIG. 5 and FIG. 6, FIG. 5 is a schematic cross-sectional view of a structure of a light-emitting diode provided in the second embodiment of the present disclosure. FIG. 6 is a schematic top view of the light-emitting diode provided in the second embodiment of the present disclosure. FIG. 5 is a cross-sectional side view taken along the sectional line F-F′ of FIG. 6. To clearly show the shapes of the first region P1 and the second region P2, the first region P1 is shown with a fill pattern. Compared to the light-emitting diode of the first embodiment of the present disclosure, the light-emitting diode of the second embodiment is different mainly in that: the first current blocking layer 141 completely wraps the island 11, and the first electrode 21 completely wraps the first current blocking layer 141 and the island 11. By designing the first current blocking layer 141 to completely wrap the island 11, the design helps to increase the area of the ODR reflection layer and further enhances reflection efficiency.

### Third Embodiment

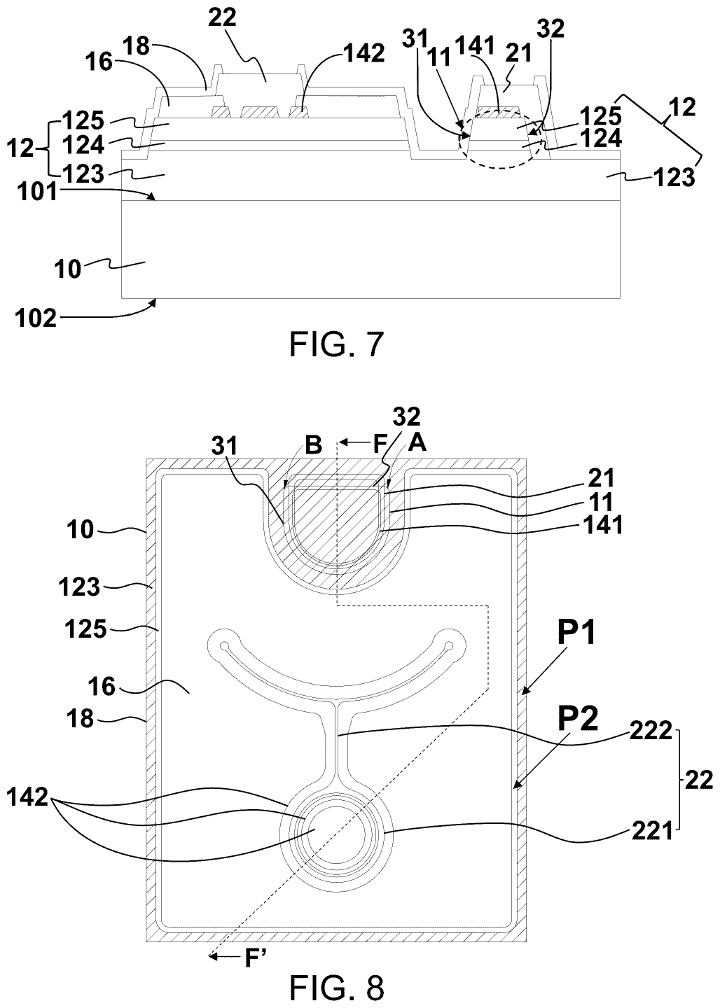

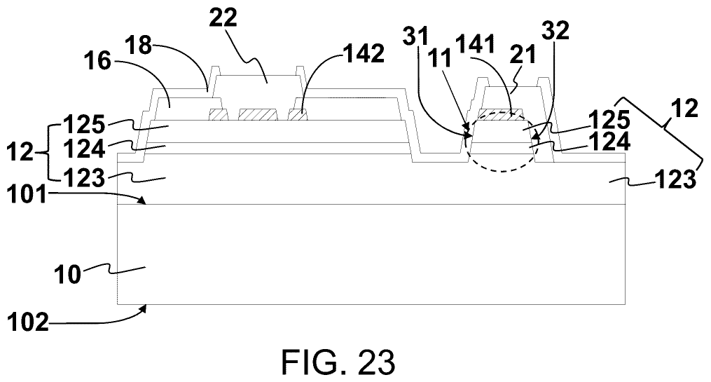

Please refer to FIG. 7 and FIG. 8, FIG. 7 is a schematic cross-sectional view of a structure of a light-emitting diode provided in the third embodiment of the present disclosure. FIG. 8 is a schematic top view of the light-emitting diode provided in the third embodiment of the present disclosure. FIG. 7 is a cross-sectional side view taken along the sectional line F-F′ of FIG. 8. To clearly show the shapes of the first region P1 and the second region P2, the first region P1 is shown with a fill pattern. Compared to the light-emitting diode of the first embodiment of the present disclosure, the light-emitting diode of the third embodiment is different mainly in that: the first electrode 21 at least covers a portion of the upper surface of the first current blocking layer 141 and a portion of the upper surface of the island 11, that is, the first electrode 21 may not completely wrap the first current blocking layer 141 and the island 11. As shown in FIG. 7, in this embodiment, the first electrode 21 may completely wrap the first current blocking layer 141 and only cover a portion of the upper surface of the island 11. In some embodiments, the design may also be: the first electrode 21 only covers a portion of the upper surface of the first current blocking layer 141 and a portion of the upper surface of the island 11 (see the eighth embodiment in FIG. 23 to FIG. 25 for details), the embodiments of the present disclosure are not limited thereto. When looking down at the semiconductor stack 12 from the top of the light-emitting diode, a percentage value of an overlapping area between the first electrode 21 and the first current blocking layer 141 to a projection area of the first current blocking layer 141 on the first semiconductor layer 123 is not less than 50%. On one hand, such design may ensure the area of the first current blocking layer 141 directly below the first electrode 21, thereby forming a good ODR reflection layer and enhancing reflection efficiency. On the other hand, such design helps to enhance the stability of the first electrode 21 and further improve an optoelectronic effect of the light-emitting diode. As shown in FIG. 8, when looking down at the semiconductor stack 12 from the top of the light-emitting diode, the island 11 has a near edge 31 and a far edge 32. A distance from the near edge 31 to the second region P2 is less than a distance from the far edge 32 to the second region P2, and a shortest distance from the island 11 to the second region P2 is the distance from the near edge 31 to the second region P2. In other words, the near edge 31 refers to the shortest edge from the island 11 to the second region P2 (as illustrated by the line segment from point A to point B in a clockwise direction in FIG. 8, representing near edge 31). All other edges, being farther from the second region P2 in comparison to the near edge 31, are consequently defined as the far edge 32. That is to say, the far edge 32 refers to all other edges of the island 11 except the near edge 31, i.e., the island 11 only has the near edge 31 and the far edge 32. In this embodiment, the first electrode 21 only covers a portion of the far edge 32. By designing the first electrode 21 to partially wrap the island 11, specifically the first electrode 21 at least covers a portion of the far edge 32, more preferably, the first electrode 21 only covers the far edge 32, that is, the first electrode 21 only covers the side surface of the island 11 away from the second region P2, it is possible to increase the distance between the first electrode 21 and the second electrode 22, thus reducing an electric field strength, enhancing the resistance to metal migration, and further improving the reliability of the light-emitting diode.

### Fourth Embodiment

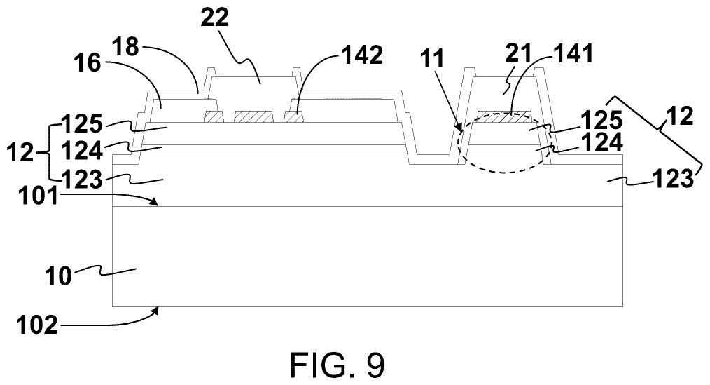

Please refer to FIG. 9, FIG. 9 is a schematic cross-sectional view of a structure of a light-emitting diode provided in the fourth embodiment of the present disclosure. Compared to the light-emitting diode of the first embodiment of the present disclosure, the light-emitting diode of the fourth embodiment is different mainly in that: in this embodiment, the upper surface of the first electrode 21 is aligned with the upper surface of the second electrode 22. This further reduces the height difference between the first electrode 21 and the second electrode 22, facilitating subsequent packaging and wire bonding.

### Fifth Embodiment

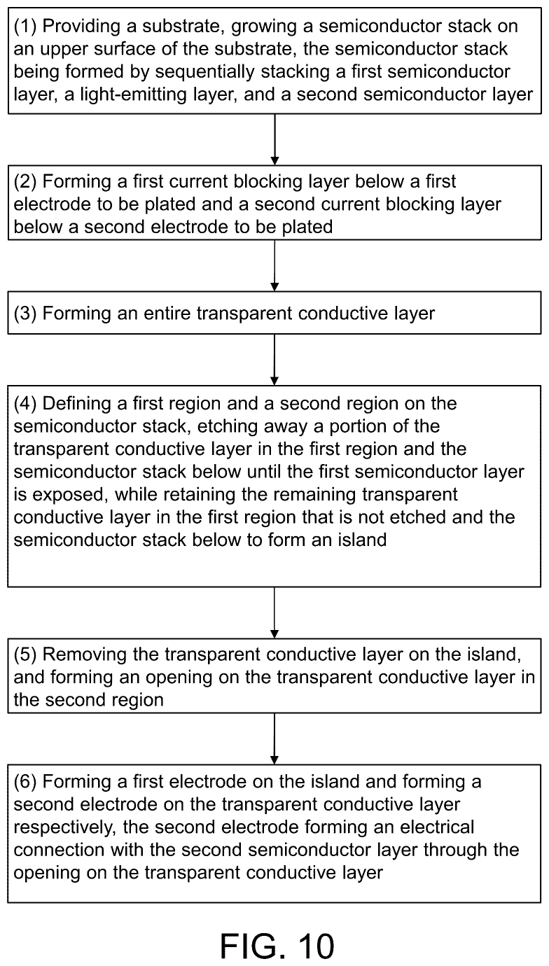

Another embodiment of the present disclosure provides a manufacturing method of a light-emitting diode, please refer to FIG. 10, which at least includes the following steps:

(1) Providing a substrate 10, growing a semiconductor stack 12 on an upper surface 101 of the substrate 10, the semiconductor stack 12 being formed by sequentially stacking the first semiconductor layer 123, the light-emitting layer 124, and the second semiconductor layer 125;

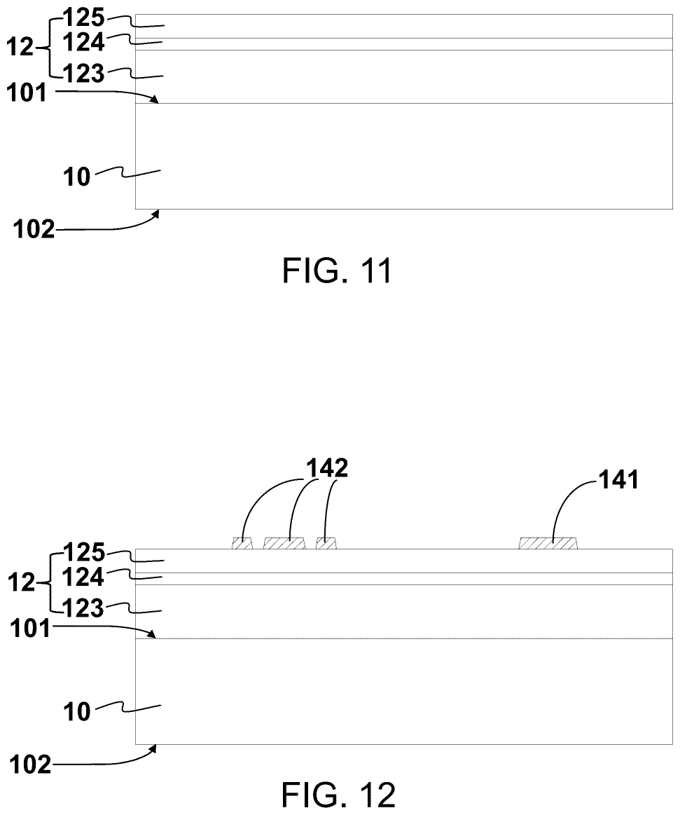

Refer to FIG. 11, the substrate 10 is provided. The substrate 10 has the upper surface 101 and the lower surface 102 arranged opposite to each other. Epitaxial growth is performed on the upper surface 101 of the substrate 10, sequentially growing the semiconductor stack 12 formed by stacking the first semiconductor layer 123, the light-emitting layer 124, and the second semiconductor layer 125. This embodiment takes the first semiconductor layer 123 as an N-type layer and the second semiconductor layer 125 as a P-type layer as an example. In an optional embodiment, the first semiconductor layer 123 provides electrons by doping with n-type impurities, and the n-type impurities may be, for example, Si, Ge, Sn, Se, and Te, etc., to provide electrons for radiative recombination. The second semiconductor layer 125 provides holes by doping with p-type impurities, the p-type impurities may be Mg, Zn, Ca, Sr, C, Ba, etc. The light-emitting layer 124 includes multiple quantum well layers and multiple quantum barrier layers alternately arranged in a repeated manner.

(2) Forming the first current blocking layer 141 below the first electrode 21 to be plated and the second current blocking layer 142 below the second electrode 22 to be plated;

Refer to FIG. 12, an entire current blocking layer is fabricated first. In this embodiment, a SiO₂ layer may be selected as the current blocking layer, then photolithography and etching are performed to remove a portion of the SiO₂ layer, retaining the SiO₂ layer below the first electrode 21 to be plated as the first current blocking layer 141 and the SiO₂ layer below the second electrode 22 to be plated as the second current blocking layer 142, and a photoresist is removed subsequently. In this embodiment, the first current blocking layer 141 and the second current blocking layer 142 are completed through the same fabrication process without requiring additional process steps, so that cost is not increased.

(3) Forming the entire transparent conductive layer 16;

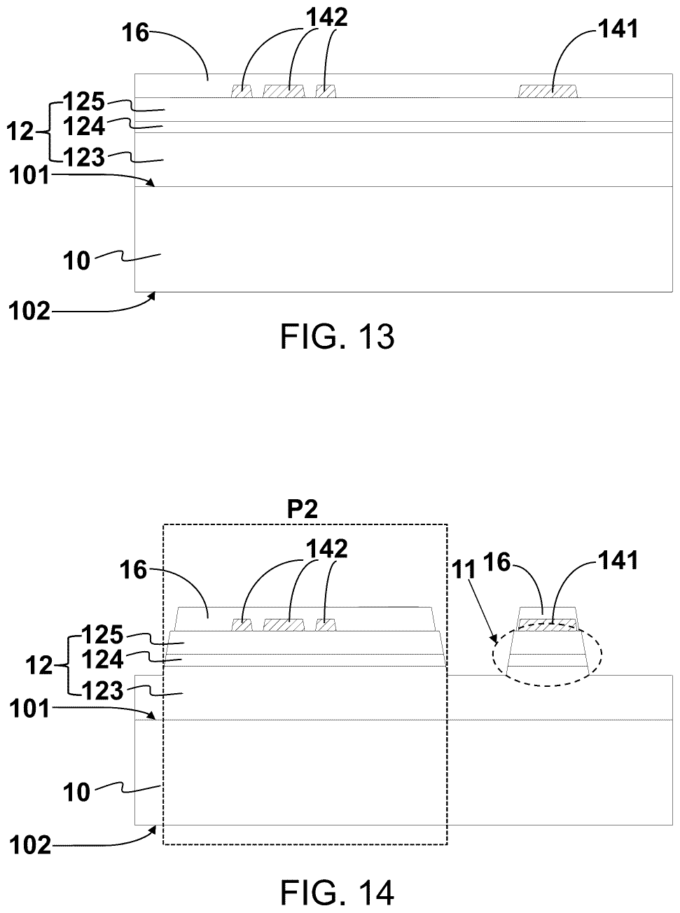

Refer to FIG. 13, the entire transparent conductive layer 16 is formed on the semiconductor stack 12, the first current blocking layer 141, and the second current blocking layer 142. In this embodiment, the transparent conductive layer 16 is preferably an ITO (indium tin oxide semiconductor transparent conductive film) layer formed by an evaporation process or a sputtering process.

(4) Defining the first region P1 and the second region P2 on the semiconductor stack 12, etching away a portion of the transparent conductive layer 16 in the first region P1 and the semiconductor stack 12 below until the first semiconductor layer 123 is exposed, while retaining the remaining transparent conductive layer 16 in the first region P1 that is not etched and the semiconductor stack 12 below to form the island 11;

Refer to FIG. 14, the first region P1 and the second region P2 are defined on the semiconductor stack 12, and the second region P2 is shown by a box illustrated with dashed lines. A photoresist coating is formed at the position of the first electrode 21 to be plated in the first region P1 and the second region P2. The semiconductor stack 12 is etched downward from one side of the second semiconductor layer 125. The transparent conductive layer 16 and the semiconductor stack 12 below in areas not covered by the photoresist are etched away, until the first semiconductor layer 123 is exposed. Optionally, the second semiconductor layer 125 and the light-emitting layer 124 are etched in sequence from one side of the second semiconductor layer 125 until the first semiconductor layer 123 is exposed, or the second semiconductor layer 125, the light-emitting layer 124, and a portion of the first semiconductor layer 123 are etched in sequence from one side of the second semiconductor layer 125 to expose the first semiconductor layer 123. Thus, a portion of the retained semiconductor stack 12 may form the second region P2 as the light-emitting region of the light-emitting diode element, and another portion of the retained semiconductor stack 12 may form the island 11 at the position of the first electrode 21 to be plated. In this embodiment, patterning the transparent conductive layer 16 and the semiconductor stack 12 based on the same mask may effectively reduce the spacing from the edge of the transparent conductive layer 16 to the edge of the second semiconductor layer 125, thereby increasing the light-emitting area. Moreover, the formed edge of the transparent conductive layer 16 is located on the inner side of the edge of the second semiconductor layer 125, and there is a spacing between the edge of the transparent conductive layer 16 and the edge of the second semiconductor layer 125, the spacing is not greater than 2.5 μm. Preferably, in some embodiments, the spacing d is not greater than 1.5 μm, for example, 1 μm. By reducing the distance from the edge of the transparent conductive layer 16 to the edge of the second semiconductor layer 125, it is possible to increase the area of the transparent conductive layer 16, thus further increasing the area of the light-emitting region, and further enhancing of the brightness of the light-emitting diode. More preferably, in some embodiments, the spacing d is not less than 0.5 μm, for example, the spacing d is between 0.5 μm to 2.5 μm. In this way, it is possible to avoid reverse aging phenomenon caused by residual transparent conductive layer at the edge of the transparent conductive layer 16 due to incomplete etching.

(5) Removing the transparent conductive layer 16 on the island 11, and forming an opening on the transparent conductive layer 16 in the second region P2;

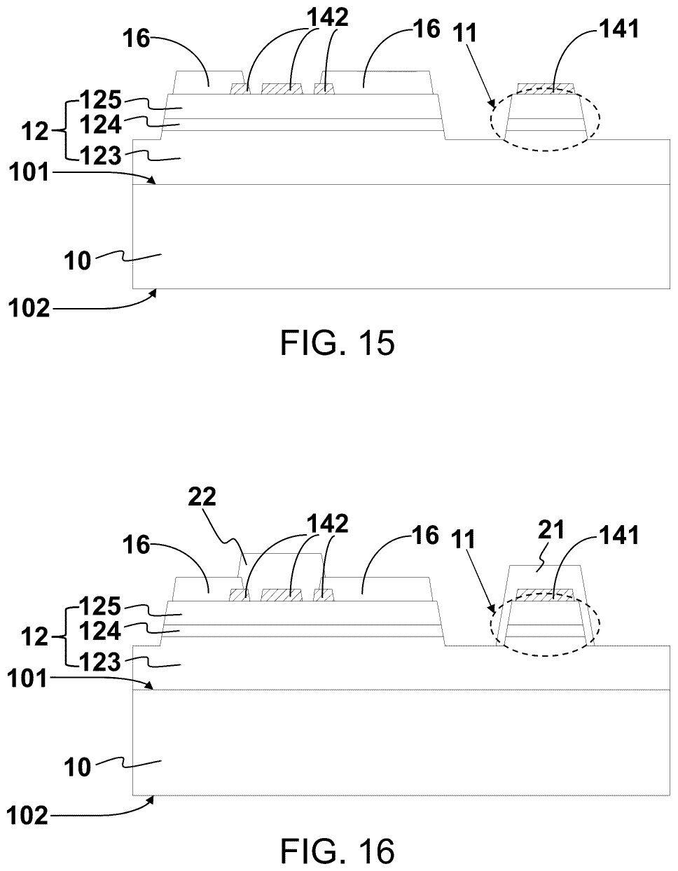

Refer to FIG. 15, the transparent conductive layer 16 on the first current blocking layer 141 above the island 11 is removed through etching, thereby exposing the first current blocking layer 141. In the meantime, the opening is formed on the transparent conductive layer 16 in the second region P2, thereby exposing portions of the second current blocking layer 142 and the second semiconductor layer 125.

(6) Forming the first electrode 21 on the island 11 and forming the second electrode 22 on the transparent conductive layer 16 respectively, the second electrode 22 forming an electrical connection with the second semiconductor layer 125 through the opening on the transparent conductive layer 16.

Refer to FIG. 16, the second electrode 22 is formed on the transparent conductive layer 16 above the second region P2, and the second electrode 22 forms the electrical connection with the second semiconductor layer 125 through the opening of the transparent conductive layer 16. In the present embodiment, the second electrode 22 may be a P electrode. The first electrode 21 is formed on the first current blocking layer 141 above the island 11. Optionally, the first electrode 21 may completely wrap the first current blocking layer 141 and the island 11, and electrically connect with the exposed first semiconductor layer 123 through covering the side surfaces of the first current blocking layer 141 and the island 11, or the first electrode 21 may only cover portions of the upper surfaces of the first current blocking layer 141 and the island 11, and electrically connect with the exposed first semiconductor layer 123 through covering the side surfaces of the first current blocking layer 141 and the island 11 away from the second region P2, which is specifically described in the third embodiment. In the present embodiment, the first electrode 21 may be an N electrode.

### Sixth Embodiment

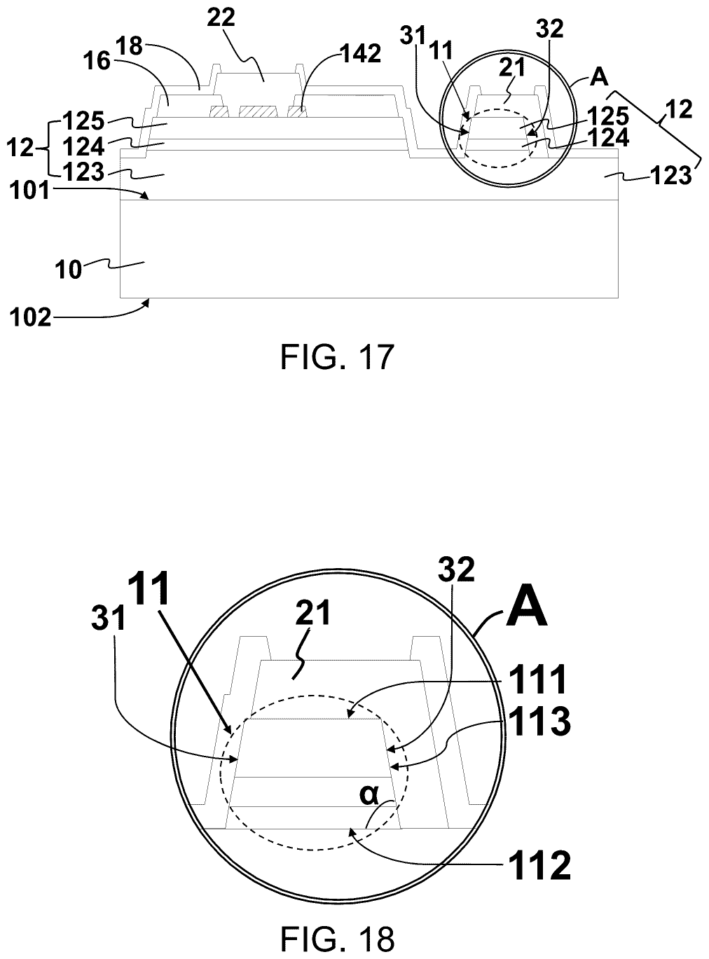

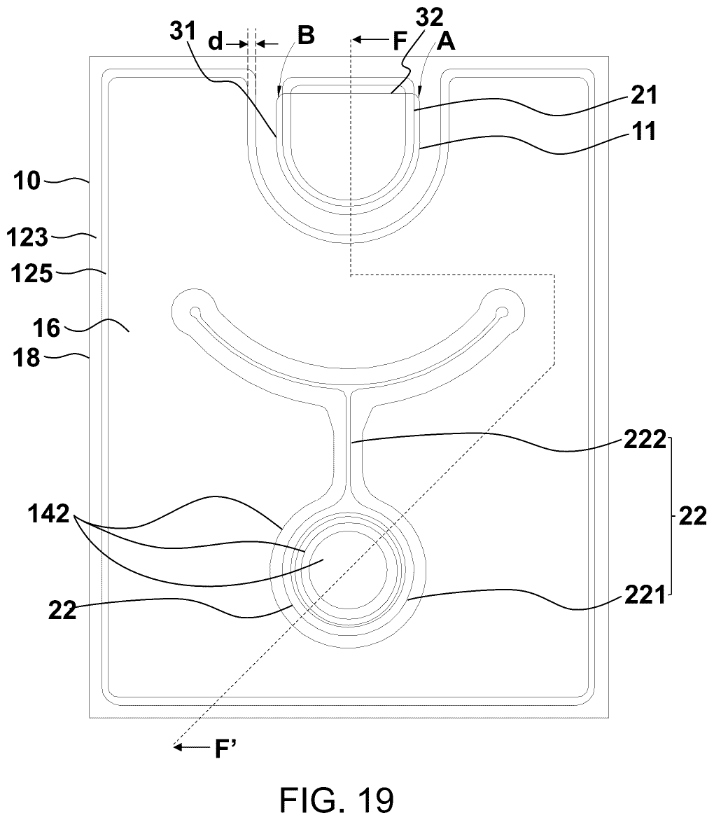

Refer to FIG. 17 to FIG. 19, FIG. 17 is a schematic cross-sectional side view of a light-emitting diode provided in the sixth embodiment of the present disclosure. FIG. 18 is a partial enlarged view of a region A in FIG. 17. FIG. 19 is a schematic top view of a light-emitting diode provided in the sixth embodiment of the present disclosure. FIG. 17 is a schematic cross-sectional side view taken along the sectional line F-F′ in FIG. 19. An embodiment of the present disclosure provides a light-emitting diode. The light-emitting diode may at least include the substrate 10, the semiconductor stack 12, the first electrode 21 and the second electrode 22.

When looking down at the semiconductor stack 12 from the top of the light-emitting diode, the semiconductor stack 12 includes the first region P1 and the second region P2, as shown in FIG. 4.

The island 11 has the upper surface 111 and the lower surface 112 arranged opposite to each other, and the near edge 31 (as illustrated by the line segment from point A to point B in a clockwise direction in FIG. 19, representing near edge 31) and the far edge 32 (the far edge 32 refers to all other edges of the island 11 except the near edge 31).

The first electrode 21 is located on the island 11, and at least partially covers the upper surface 111 and the far edge 32 of the island 11, and electrically connects with the exposed first semiconductor layer 123 through covering the side surface where the far edge 32 of the island 11 is located. As an example, in the present embodiment, the first electrode 21 may be an N electrode. The present disclosure arranges the first electrode 21 to at least partially cover the upper surface 111 of the island 11 and the far edge 32 away from the second region P2, so that the spacing between the first electrode 21 and the second electrode 22 is effectively increased, thus reducing electric field intensity, enhancing resistance to metal migration, and further improving the reliability of the light-emitting diode. In a preferred embodiment, the first electrode 21 may also be arranged to only cover the far edge 32 away from the second region P2. More preferably, the first electrode 21 only covers a portion of the far edge 32, thereby achieving complete isolation of the electric field between the first electrode 21 and the second electrode 22, and further increasing the spacing between the first electrode 21 and the second electrode 22.

The second current blocking layer 142 is located in the second region P2. The transparent conductive layer 16 is located in the second region P2 and covers the second current blocking layer 142. The second current blocking layer 142 is sandwiched between the semiconductor stack 12 and the transparent conductive layer 16. The second electrode 22 is located on the transparent conductive layer 16, and electrically connects with the second semiconductor layer 125 through the transparent conductive layer 16. The second electrode 22 includes the main body portion 221 and the at least one extension portion 222. The second electrode 22 corresponds to and contacts the second current blocking layer 142 in a vertical direction, that is, the projection of the second electrode 22 on the second current blocking layer 142 is located inside the second current blocking layer 142. As an example, the second electrode 22 may be a P electrode. It should be noted that the second current blocking layer 142 in the embodiments of the present disclosure may include both the first portion and the second portion as shown in the drawings of the present disclosure. The first portion is formed directly below the extension portion 222 and a portion of the main body portion 221 of the second electrode 21. The first portion has an opening directly below the main body portion 221, and the second portion is formed within the opening and there is a gap between the second portion and the first portion. In some embodiments, the second current blocking layer 142 may also include only the first portion; in other embodiments, the second current blocking layer 142 may also include only the second portion, and the present disclosure is not limited to the examples listed herein.

The edge of the transparent conductive layer 16 is located on the inner side of the edge of the second semiconductor layer 125. There is a spacing d between the edge of the transparent conductive layer 16 and the edge of the second semiconductor layer 125, and the spacing d is not greater than 2.5 μm. Preferably, in some embodiments, the spacing d is not greater than 1.5 μm, for example, 1 μm. By reducing the distance from the edge of the transparent conductive layer 16 to the edge of the second semiconductor layer 125, the area of the transparent conductive layer 16 is increased, thereby increasing the area of the light-emitting region and further improving the brightness of the light-emitting diode. More preferably, in some embodiments, the spacing d is not less than 0.5 μm, for example, the spacing d is between 0.5 μm to 2.5 μm. In this way, it is possible to avoid reverse aging phenomenon caused by residual transparent conductive layer at the edge of the transparent conductive layer 16 due to incomplete etching.

The island 11 includes the first semiconductor layer 123, the light-emitting layer 124, and the second semiconductor layer 125 stacked in sequence. More preferably, in the present embodiment, the upper surface 111 of the island 11 is aligned with the upper surface of the second region P2. By etching a portion of the semiconductor stack 12 to expose the first semiconductor layer 123, the island 11 and the second region P2 are formed simultaneously. On one hand, this process is simple and does not require additional process steps; on the other hand, this process helps to reduce the height difference between the first electrode 21 and the second electrode 22, facilitating subsequent packaging and wire bonding.

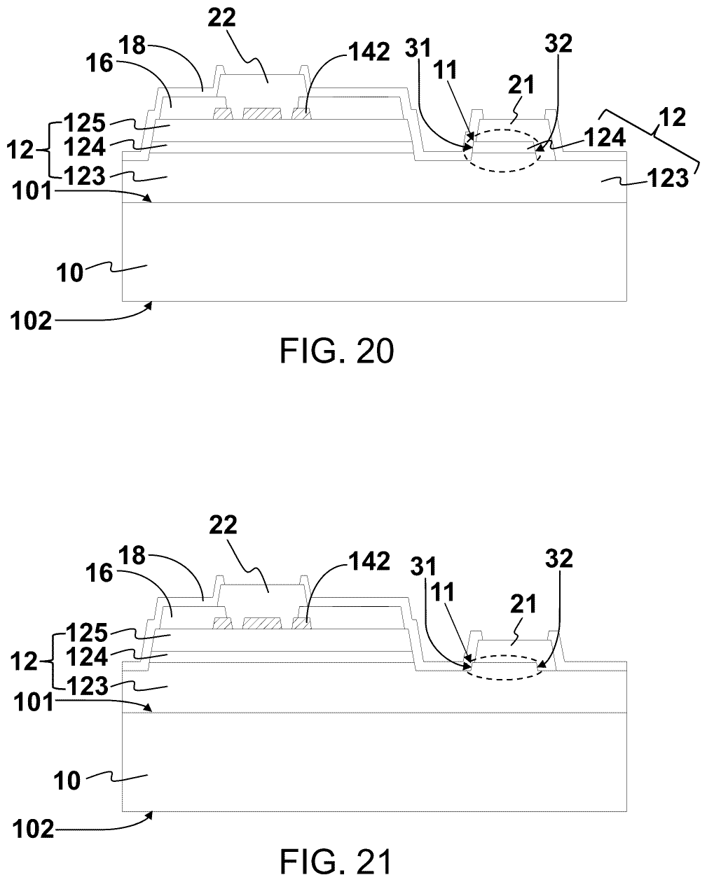

In some embodiments, refer to FIG. 20, FIG. 20 is a schematic cross-sectional view of a structure of another light-emitting diode provided in an embodiment of the present disclosure. The island 11 may also include only the first semiconductor layer 123 and the light-emitting layer 124 stacked in sequence. Or, refer to FIG. 21, FIG. 21 is a schematic cross-sectional view of a structure of yet another light-emitting diode provided by an embodiment of the present disclosure. The island 11 may also include only the first semiconductor layer 123, and the embodiments of the present disclosure are not limited thereto. In the embodiments of the present disclosure, the key point lies in ensuring that the first electrode 21 is disposed to at least partially cover the upper surface 111 of the island 11 and the far edge 32 away from the second region P2, so as to achieve the technical effects of the present disclosure.

Preferably, in an embodiment, the island 11 has the side surface 113 connecting the upper surface 111 of the island 11 and the lower surface 112 of the island 11, and the interior angle α formed between the side surface 113 and the lower surface 112 of the island 11 is less than 90°(as shown in FIG. 18), which helps to enhance the coverage of the first electrode 21. Preferably, in some embodiments, α is less than 60°, more preferably, in some embodiments, α is less than 45°, for example, 30° to 40°, 20° to 30°, etc.

Further, the light-emitting diode may also include the insulating layer 18. The insulating layer 18 covers the semiconductor stack 12, and may also cover a portion of the first electrode 21 and a portion of the second electrode 22, and the embodiments of the present disclosure are not limited thereto. The specific structure, performance and advantages thereof may be derived from the aforementioned content, and will not be elaborated here.

### Seventh Embodiment

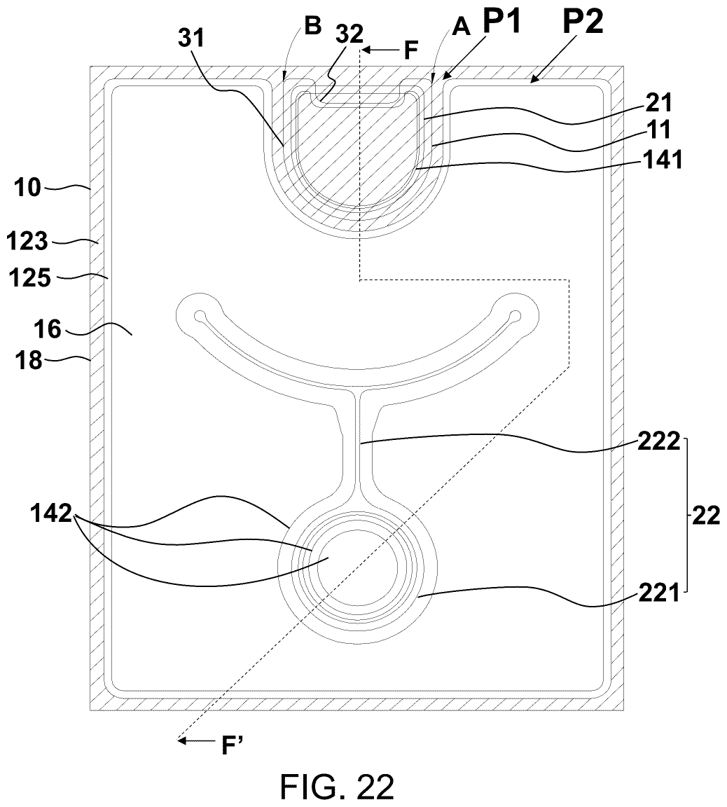

Refer to FIG. 22, FIG. 22 is a schematic top view of a light-emitting diode provided in the seventh embodiment of the present disclosure, which is a further design of the third embodiment of the present disclosure. Compared with the light-emitting diode of the third embodiment, the present embodiment is different mainly in that: the first current blocking layer 141 and the island 11 are arranged in a horseshoe shape, that is, having a recess in a central region of the far edge 32 away from the second region P2, so that the first electrode 21 only covers a portion of the far edge 32, thereby achieving complete isolation of the electric field between the first electrode 21 and the second electrode 22, and further increasing the spacing between the first electrode 21 and the second electrode 22.

### Eighth Embodiment

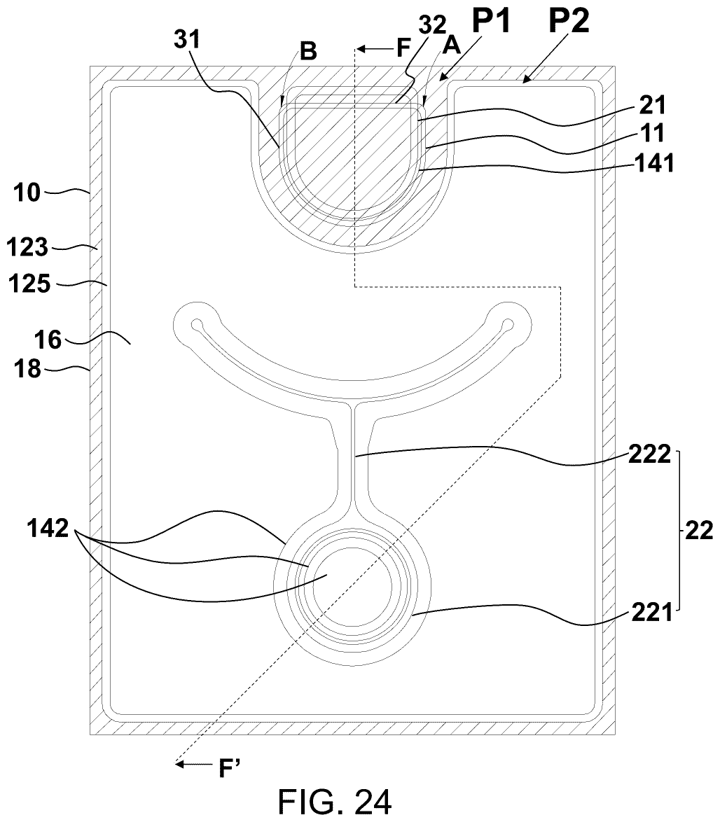

Refer to FIG. 23 to FIG. 24, FIG. 23 is a schematic cross-sectional view of a structure of a light-emitting diode provided in the eighth embodiment of the present disclosure. FIG. 24 is a schematic top view of the light-emitting diode provided in the eighth embodiment of the present disclosure. The present embodiment is different mainly in that: the first electrode 21 only covers a portion of the upper surface of the first current blocking layer 141 and a portion of the upper surface of the island 11. Such design helps to increase the area of the first current blocking layer 141, thereby increasing the area of the ODR reflection layer, and further enhancing reflection efficiency.

In an embodiment, when looking down at the semiconductor stack 12 from the top of the light-emitting diode, the percentage value of the overlapping area between the first electrode 21 and the first current blocking layer 141 to the projection area of the first current blocking layer 141 on the first semiconductor layer 123 is not less than 50%. Generally speaking, the more the overlapping area between the first electrode 21 and the first current blocking layer 141, that is, the larger the area of the first current blocking layer 141 directly below the first electrode 21, and the larger the area of the formed ODR reflection layer, so that reflection efficiency may be improved more effectively. However, the larger the area of the first current blocking layer 141, the less the contact area between the first electrode 21 and the semiconductor stack 12. Since the adhesion between the first electrode 21 and the first current blocking layer 141 is not as good as the adhesion between the first electrode 21 and the semiconductor stack 12, appropriately setting the percentage value of the overlapping area between the first electrode 21 and the first current blocking layer 141 to the projection area of the first current blocking layer 141 on the first semiconductor layer 123 helps to enhance the stability of the first electrode 21 while ensuring the formation of a good ODR reflection layer, thereby further improving the optoelectronic effect of the light-emitting diode.

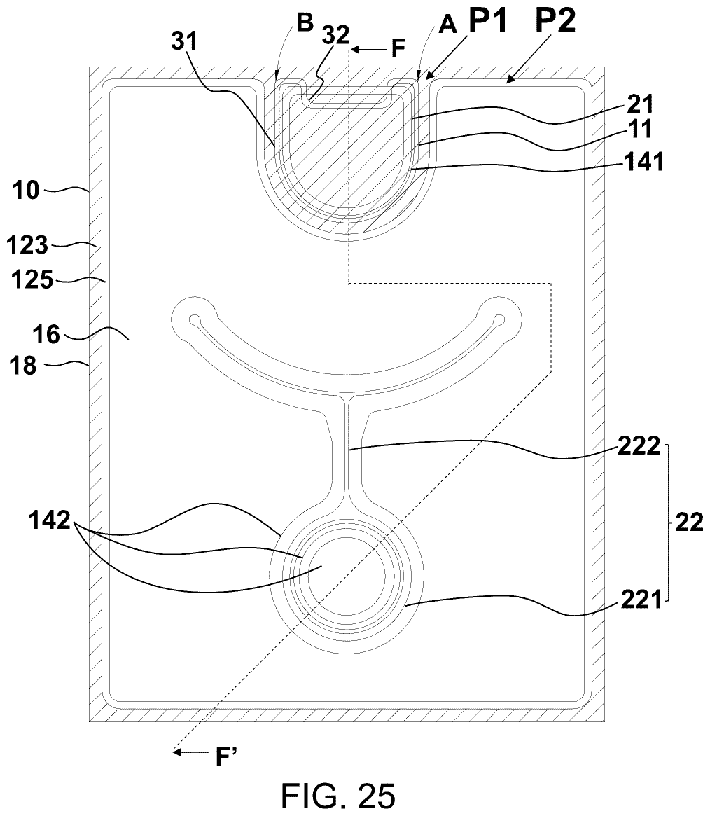

Further, in some embodiments, as shown in FIG. 25, it is also possible to design the shapes of the first current blocking layer 141 and the island 11 as a horseshoe shape, that is, having the recess in the central region of the far edge 32 away from the second region P2, so that the first electrode 21 only covers a portion of the far edge 32, thereby achieving complete isolation of the electric field between the first electrode 21 and the second electrode 22, and further increasing the spacing between the first electrode 21 and the second electrode 22.

### Ninth Embodiment

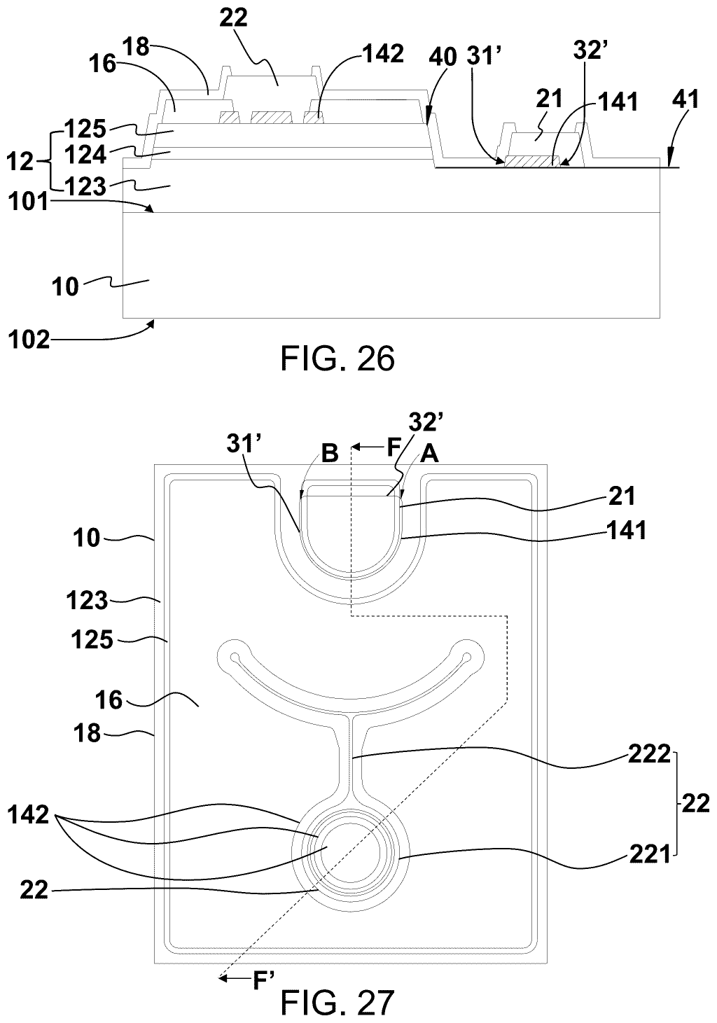

Refer to FIG. 26 to FIG. 27, FIG. 26 is a schematic cross-sectional view of a structure of a light-emitting diode provided in the ninth embodiment of the present disclosure. FIG. 27 is a schematic top view of the light-emitting diode provided in the ninth embodiment of the present disclosure. Compared to the light-emitting diodes of other embodiments of the present disclosure, the present embodiment is different mainly in that: the semiconductor stack 12 is provided with a step 40 that sequentially passes through a portion of the second semiconductor layer 125 and the light-emitting layer 124 and extends to the first semiconductor layer 123, and a step surface 41 that exposes a portion of the first semiconductor layer 123. The semiconductor stack 12 forms the step surface 41 by etching away portions of the second semiconductor layer 125 and the light-emitting layer 124 to expose the first semiconductor layer 123, and the first current blocking layer 141 is located on the step surface 41.

When looking down at the semiconductor stack 12 from the top of the light-emitting diode, the first current blocking layer 141 has the upper surface and the lower surface opposite to each other, as well as a near edge 31′ and a far edge 32′. A distance from the near edge 31′ to the step 40 is less than a distance from the far edge 32′ to the step 40, and the shortest distance from the island 11 to the step 40 is a distance from the near edge 31′ to the step 40. In other words, the near edge 31′ refers to the shortest edge from the first current blocking layer 141 to the step 40 (as illustrated by the line segment from point A to point B in a clockwise direction in FIG. 27, representing near edge 31′), and the remaining edges are all farther from the step 40 relative to the near edge 31′, thus defined as the far edge 32′. That is to say, the far edge 32′ refers to all other edges of the first current blocking layer 141 except the near edge 31′, i.e., the first current blocking layer 141 only has the near edge 31′ and the far edge 32′.

The first electrode 21 is located on the first current blocking layer 141, and at least partially covers the upper surface and the far edge 32′ of the first current blocking layer 141, and is electrically connected to the exposed first semiconductor layer 123 through covering the side surface where the far edge 32′ of the first current blocking layer 141 is located. As an example, in the present embodiment, the first electrode 21 may be an N electrode. By arranging the first current blocking layer 141 on the exposed first semiconductor layer 123 and arranging the first electrode 21 to at least partially cover the upper surface and the far edge 32′ away from the step 40 of the first current blocking layer 141, on one hand, the present disclosure effectively increases the spacing between the first electrode 21 and the second electrode 22, thereby reducing electric field intensity, enhancing resistance to metal migration, and further improving the reliability of the light-emitting diode; on the other hand, the present disclosure may also effectively improve the current crowding phenomenon below the first electrode 21, promote lateral spreading of current, and form a good ODR reflection layer to enhance reflection efficiency, further improving the optoelectronic effect of the light-emitting diode. In a preferred embodiment, the first electrode 21 may also be arranged to only cover the far edge 32′ away from the step 40. More preferably, the first electrode 21 only covers a portion of the far edge 32′, thereby achieving complete isolation of the electric field between the first electrode 21 and the second electrode 22, and further increasing the spacing between the first electrode 21 and the second electrode 22.

In an embodiment, when looking down at the semiconductor stack 12 from the top of the light-emitting diode, the percentage value of the overlapping area between the first electrode 21 and the first current blocking layer 141 to the projection area of the first current blocking layer 141 on the first semiconductor layer 123 is not less than 50%. Generally speaking, the more the overlapping area between the first electrode 21 and the first current blocking layer 141, that is, the larger the area of the first current blocking layer 141 directly below the first electrode 21, and the larger the area of the formed ODR reflection layer, so that reflection efficiency may be improved more effectively. However, the larger the area of the first current blocking layer 141, the less the contact area between the first electrode 21 and the semiconductor stack 12. Since the adhesion between the first electrode 21 and the first current blocking layer 141 is not as good as the adhesion between the first electrode 21 and the semiconductor stack 12, appropriately setting the percentage value of the overlapping area between the first electrode 21 and the first current blocking layer 141 to the projection area of the first current blocking layer 141 on the first semiconductor layer 123 helps to enhance the stability of the first electrode 21 while ensuring the formation of a good ODR reflection layer, thereby further improving the optoelectronic effect of the light-emitting diode.

Preferably, in an embodiment, the first current blocking layer 141 has the upper surface and the lower surface, and the side surface connected to the upper surface and the lower surface. The interior angle formed between the side surface and the lower surface of the first current blocking layer 141 is less than 90°. Preferably, in some embodiments, the interior angle is less than 60°, more preferably, in some embodiments, the interior angle is less than 45°, for example, 30° to 40°, 20° to 30°, etc., which helps to enhance the coverage of the first electrode 21.

The second current blocking layer 142 is located on the second semiconductor layer 125. The transparent conductive layer 16 is located in the second region P2 and covers the second current blocking layer 142, and the second current blocking layer 142 is sandwiched between the semiconductor stack 12 and the transparent conductive layer 16. The second electrode 22 is located on the transparent conductive layer 16, and is electrically connected to the second semiconductor layer 125 through the transparent conductive layer 16. Further, the light-emitting diode may also include the insulating layer 18. The insulating layer 18 covers the semiconductor stack 12, and may also cover a portion of the first electrode 21 and a portion of the second electrode 22. The specific structure, performance and advantages thereof may be derived from the aforementioned content, which will not be elaborated here.

It should also be noted that the light-emitting diodes provided by the above embodiments are also applicable to chips with a high-voltage structure. The chip with the high-voltage structure includes multiple light-emitting units. Each of the light-emitting units includes the semiconductor stack 12. Adjacent light-emitting units are isolated from each other by isolation trenches on the substrate, and electrical connection is achieved through interconnected electrodes spanning across the isolation trenches. A third current blocking layer is disposed below the interconnected electrodes to achieve current blocking function and avoid current crowding phenomenon. The first current blocking layer 141 and the island 11 as described in the above embodiments are disposed below the first electrode 21. The specific structure, performance and advantages thereof may be derived from the aforementioned content, which will not be elaborated here.

The present disclosure also provides a light-emitting device, adopting the light-emitting diode as described in any one of the above embodiments, which may effectively improve the performance of the light-emitting device.

Finally, it should be noted that: the above embodiments are only used to illustrate the technical solutions of the present disclosure, rather than limiting them. Although the present disclosure has been described in detail with reference to the aforementioned embodiments, those skilled in the art should understand that: they may still modify the technical solutions described in the aforementioned embodiments, or perform equivalent substitutions for some or all of the technical features therein; and these modifications or substitutions do not cause the essence of the corresponding technical solutions to depart from the scope of the technical solutions of the embodiments of the present disclosure.

What is claimed is:

1. A light-emitting diode, the light-emitting diode comprising:
a substrate, having an upper surface and a lower surface disposed opposite to each other;
a semiconductor stack, disposed on the upper surface of the substrate, and comprising a first semiconductor layer, a light-emitting layer, and a second semiconductor layer stacked in sequence, wherein when looking down at the semiconductor stack from a top of the light-emitting diode, the semiconductor stack comprises a first region and a second region, and the first region comprises an exposed first semiconductor layer and a retained island;
a first current blocking layer, located on the island;
a second current blocking layer, located in the second region;
a transparent conductive layer, located in the second region and covering the second current blocking layer;
a first electrode, located on the first current blocking layer and electrically connected to the exposed first semiconductor layer; and
a second electrode, located on the transparent conductive layer and electrically connected to the second semiconductor layer.

2. The light-emitting diode according to claim 1, wherein the second region comprises the first semiconductor layer, the light-emitting layer and the second semiconductor layer stacked in sequence, and the second region is all regions in the semiconductor stack except the first region

3. The light-emitting diode according to claim 1, wherein the island comprises the first semiconductor layer, the light-emitting layer and the second semiconductor layer stacked in sequence.

4. The light-emitting diode according to claim 1, wherein the first electrode completely wraps the first current blocking layer and the island.

5. The light-emitting diode according to claim 1, wherein the first electrode at least covers the first current blocking layer and a portion of an upper surface of the island.

6. The light-emitting diode according to claim 5, wherein when looking down at the semiconductor stack from the top of the light-emitting diode, the island has a near edge and a far edge, a distance from the near edge to the second region is less than a distance from the far edge to the second region, and the first electrode at least covers a portion of the far edge.

7. The light-emitting diode according to claim 1, wherein the first current blocking layer completely wraps the island.

8. The light-emitting diode according to claim 1, wherein an edge of the transparent conductive layer is located on an inner side of an edge of the second semiconductor layer, there is a spacing between the edge of the transparent conductive layer and the edge of the second semiconductor layer, and the spacing is not greater than 2.5 μm.

9. The light-emitting diode according to claim 1, wherein the island has an upper surface, a lower surface, and a side surface connecting the upper surface and the lower surface of the island, an interior angle formed between the side surface and the lower surface of the island is less than 90°.

10. The light-emitting diode according to claim 1, wherein the upper surface of the island is aligned with the upper surface of the second region.

11. A manufacturing method of a light-emitting diode, comprising the following steps:
(1) providing a substrate, growing a semiconductor stack on an upper surface of the substrate, the semiconductor stack being formed by sequentially stacking a first semiconductor layer, a light-emitting layer, and a second semiconductor layer;
(2) forming a first current blocking layer below a first electrode to be plated and a second current blocking layer below a second electrode to be plated;
(3) forming an entire transparent conductive layer;
(4) defining a first region and a second region on the semiconductor stack, etching away a portion of the transparent conductive layer in the first region and the semiconductor stack below until the first semiconductor layer is exposed, while retaining the remaining transparent conductive layer in the first region that is not etched and the semiconductor stack below to form an island;
(5) removing the transparent conductive layer on the island, and forming an opening on the transparent conductive layer in the second region;
(6) forming a first electrode on the island and forming a second electrode on the transparent conductive layer respectively, the second electrode forming an electrical connection with the second semiconductor layer through the opening on the transparent conductive layer.

12. The manufacturing method of the light-emitting diode according to claim 11, wherein the first current blocking layer and the second current blocking layer are simultaneously formed in the step (2).

13. The manufacturing method of the light-emitting diode according to claim 11, wherein in the step (4), the transparent conductive layer and the semiconductor stack are patterned based on a same mask.

14. The manufacturing method of the light-emitting diode according to claim 13, wherein an edge of the transparent conductive layer formed according to the method in the step (4) is located on an inner side of an edge of the second semiconductor layer, there is a spacing between the edge of the transparent conductive layer and the edge of the second semiconductor layer, and the spacing is not greater than 2.5 μm.

15. A light-emitting diode, comprising:
a substrate, having an upper surface and a lower surface disposed opposite to each other;
a semiconductor stack, disposed on the upper surface of the substrate, and comprising a first semiconductor layer, a light-emitting layer, and a second semiconductor layer stacked in sequence, wherein when looking down at the semiconductor stack from a top of the light-emitting diode, the semiconductor stack comprises a first region and a second region, the first region comprises an exposed first semiconductor layer and a retained island, the island has an upper surface and a lower surface disposed opposite to each other, and a near edge and a far edge, and a distance from the near edge to the second region is less than a distance from the far edge to the second region;
a first electrode, located on the island, at least partially covering the upper surface and the far edge of the island, and electrically connected to the exposed first semiconductor layer;
a second electrode, located in the second region and electrically connected to the second semiconductor layer,
wherein the second region comprises the first semiconductor layer, the light-emitting layer and the second semiconductor layer stacked in sequence, and the second region is all regions in the semiconductor stack except the first region.

16. The light-emitting diode according to claim 15, wherein the light-emitting diode further comprises a first current blocking layer located between the island and the first electrode, and the first electrode at least covers a portion of an upper surface of the first current blocking layer.

17. The light-emitting diode according to claim 16, wherein when looking down at the semiconductor stack from the top of the light-emitting diode, a percentage value of an overlapping area between the first electrode and the first current blocking layer to a projection area of the first current blocking layer on the first semiconductor layer is not less than 50%.

18. The light-emitting diode according to claim 15, wherein the island comprises the first semiconductor layer, the light-emitting layer and the second semiconductor layer stacked in sequence; or the island comprises the first semiconductor layer and the light-emitting layer stacked in sequence; or the island comprises the first semiconductor layer.

19. The light-emitting diode according to claim 15, further comprising:
a transparent conductive layer, located in the second region and at least covering the second semiconductor layer, wherein the second electrode is electrically connected to the second semiconductor layer through the transparent conductive layer, an edge of the transparent conductive layer is located on an inner side of an edge of the second semiconductor layer, there is a spacing between the edge of the transparent conductive layer and the edge of the second semiconductor layer, and the spacing is not greater than 2.5 μm.

20. A light-emitting device, adopting the light-emitting diode according to claim 1.
